(19) United States
(12) Patent Application Publication
(10) Pub. No.: US 2026/0111632 A1
(43) Pub. Date: Apr. 23, 2026

(54) ARTIFICIAL INTELLIGENCE-BASED JOINT QUALITY PREDICTION METHOD

(71) Applicants: HYUNDAI MOTOR COMPANY, Seoul (KR); KIA CORPORATION, Seoul (KR); SOGANG UNIVERSITY RESEARCH & BUSINESS DEVELOPMENT FOUNDATION, Seoul (KR)

(72) Inventors: JiHong Lee, Hwaseong-si (KR); Dong Choul Kim, Seoul (KR); Junwon Min, Seoul (KR); In Taek Jang, Seoul (KR)

(73) Assignees: HYUNDAI MOTOR COMPANY, Seoul (KR); KIA CORPORATION, Seoul (KR); SOGANG UNIVERSITY RESEARCH & BUSINESS DEVELOPMENT FOUNDATION, Seoul (KR)

(21) Appl. No.: 19/088,732

(22) Filed: Mar. 24, 2025

(30) Foreign Application Priority Data
Oct. 23, 2024 (KR) 10-2024-0145544

(51) Int. Cl. G06F 30/27

(52) U.S. Cl. CPC G06F 30/27

(57) ABSTRACT

An artificial intelligence-based joint quality prediction method includes collecting raw data including joint cross-section analysis data and joint equipment monitoring data and generating training data by preprocessing the raw data. The artificial intelligence-based joint quality prediction method also includes training, based on the training data, a joint quality prediction model configured to output joint quality of joint equipment based on real-time data collected in real time by the joint equipment. The artificial intelligence-based joint quality prediction method additionally includes validating the trained joint quality prediction model through a K-fold cross validation.

### CROSS-REFERENCE TO RELATED APPLICATION

This application claims priority to and the benefit of Korean Patent Application No. 10-2024-0145544, filed in the Korean Intellectual Property Office on Oct. 23, 2024, the entire contents of which are hereby incorporated herein by reference.

### BACKGROUND

### (a) Technical Field

The present disclosure relates to an artificial intelligence-based joint quality prediction method, and more particularly, to an artificial intelligence-based joint quality prediction method of predicting mechanical joint cross-section quality.

### (b) Description of the Related Art

A typical self-piercing rivet (SPR)/flow drill screw (FDS) equipment self-monitoring system monitors only whether a joint process has been completed mechanically. Detailed quality (rivet interlock length, gap between panels, etc.) of a cross-section of a fastening portion that is determined as the criteria for passing a joint quality is not monitored in a typical SPR/FDS self-monitoring system.

### SUMMARY

Embodiments of the present disclosure provide an artificial intelligence-based joint quality prediction method capable of monitoring the joint quality in detail, non-destructively, and in real time through analysis of raw data (e.g., pressing force, displacement, time, etc.) of equipment generated on a control panel after equipment joint fastening of self-piercing rivet (SPR)/flow drill screw (FDS).

Embodiments of the present disclosure provide an artificial intelligence-based joint quality prediction method capable of pre-processing equipment data, training a convolutional neural network (CNN)-based joint quality prediction model with the equipment data, improving model accuracy by using a K-fold cross validation, and providing a joint quality prediction result to a user in real time through prediction software.

According to an embodiment, an artificial intelligence-based joint quality prediction method is provided. The artificial intelligence-based joint quality prediction method includes collecting raw data including joint cross-section analysis data and joint equipment monitoring data and generating training data by preprocessing the raw data. The artificial intelligence-based joint quality prediction method also includes training, based on the training data, a joint quality prediction model configured to output joint quality of joint equipment based on real-time data collected in real time by the joint equipment. The artificial intelligence-based joint quality prediction method additionally includes validating the trained joint quality prediction model through a K-fold cross validation.

The artificial intelligence-based joint quality prediction method may further include predicting the joint quality with respect to the joint equipment by using the trained joint quality prediction model. Predicting the joint quality with respect to the joint equipment may include one or both of determining whether an interlock length with respect to an SPR is defective or determining whether a step difference of a head portion and an internal gap of an FDS are defective.

Collecting the raw data including joint cross-section analysis data and joint equipment monitoring data may include selecting a plurality of combinations with respect to heterogeneous materials and collecting the raw data from a test performed using a plurality of joint methods with respect to each of the plurality of combinations.

Collecting the raw data including joint cross-section analysis data and joint equipment monitoring data may include collecting image data including a pressing force graph and a torque graph from the joint equipment as the raw data.

Generating the training data by preprocessing the raw data may include performing a preprocessing operation including one or more of data timing of the raw data, data section segmentation, noise removal, sampling transformation, or feature extraction.

Training the joint quality prediction model may include training a convolutional neural network (CNN)-based joint quality prediction model. The CNN-based joint quality prediction model may include one or more convolutional layers, one or more pooling layers, and one or more connected layers.

Training the CNN-based joint quality prediction model may include performing a convolutional operation to extract features of image data from the one or more convolutional layers and generating a feature map from the image data by using a plurality of filters, compressing a size of the feature map in the one or more pooling layers, and determining weights with respect to the features in the one or more connected layers.

Validating the trained joint quality prediction model through the K-fold cross validation may include performing training K times by using part of the training data as validation data and generating K models, determining prediction accuracies with respect to the K models by using part of the training data as evaluation data, and validating the performance of the joint quality prediction model through an average of the prediction accuracies.

Predicting the joint quality with respect to the joint equipment by using the trained joint quality prediction model may further include determining probability values with respect to a plurality of classes, and determining the joint quality as a specific class having a probability value satisfying a preset standard.

The plurality of classes may include two or more of a normal class, a defective proximity class, or a defective class. The joint quality prediction model may be a classification model configured to classify the real-time data into one of the two or more of the normal class, the defective proximity class, or the defective class.

According to another embodiment, another artificial intelligence-based joint quality prediction method is provided. The artificial intelligence-based joint quality prediction method includes selecting a joint scheme of a plurality of joint schemes. The artificial intelligence-based joint quality prediction method also includes receiving real-time data with respect to the selected joint scheme as input data from joint equipment. The artificial intelligence-based joint quality prediction method further includes predicting a joint quality based on the input data by using a joint quality prediction model trained based on training data obtained by preprocessing joint cross-section analysis data and joint equipment monitoring data with respect to the selected joint scheme.

Selecting the joint scheme of the plurality of joint schemes may include selecting at least one an SPR or an FDS as the joint scheme.

Receiving the real-time data with respect to the selected joint scheme as the input data from the joint equipment may include inputting pressing force data and torque data of the joint equipment provided in a graph as the input data.

Inputting the pressing force data and the torque data of the joint equipment provided in the graph as the input data may include inputting, as the input data, image data generated through matrix-based image conversion in which a logic one (1) is input to positions corresponding to x-coordinate and y-coordinate of each of the pressing force data and the torque data and a logic zero (0) is input to the remaining positions.

Predicting the joint quality based on the input data may include, based on selecting SPR as the joint scheme, predicting a joint cross-section quality with respect to at least one of a step difference of a head portion, a remaining thickness of a lower plate, or an interlock length. Predicting the joint quality based on the input data may include, based on selecting FDS as the joint scheme, predicting the joint cross-section quality with respect to at least one of a step difference of a head portion, an internal gap between plates, or a diagonal fastening.

Predicting the joint quality based on the input data may further include performing predictions K times by using the joint quality prediction model through a K-fold cross validation, and determining the joint quality based on a calculated average of K prediction results.

Predicting joint quality based on the input data may further include dividing the joint quality into a plurality of classes and respectively calculating the prediction results as probability values with respect to the plurality of classes, and determining the joint quality with respect to a specific class when a certain percentage (e.g., more than half) of the prediction results include the specific class having a probability value greater satisfying a preset standard.

The plurality of classes may include two or more of a normal class, a defective proximity class, or a defective class. The joint quality prediction model may be a classification model configured to classify the real-time data into one of the two or more of the normal class, the defective proximity class, or the defective class.

Predicting the joint quality based on the input data by using the joint quality prediction model may include detecting whether an interlock length of a joint cross-section in an SPR is normal, defective proximity, or defective by using a pressing force graph and a torque graph of the joint equipment as the input data.

Predicting the joint quality based on the input data by using the joint quality prediction model may include detecting whether a step difference of a head portion and an internal gap of a joint cross-section in an FDS is normal, defective proximity, defective, or pre-hole defective by using a pressing force graph and a torque graph of the joint equipment as the input data.

The artificial intelligence-based joint quality prediction method according to an embodiment of the present disclosure may monitor the joint quality in detail, non-destructively, and in real time through analysis of raw data (pressing force, displacement, time, etc.) of equipment generated on the control panel after equipment fastening.

The artificial intelligence-based joint quality prediction method according to an embodiment of the present disclosure may predict the joint quality, including the interlock length in the SPR and the internal gap between plates and the step difference of the head portion in the FDS, by inputting the real-time raw data obtainable from the equipment monitoring system of SPR/FDS by using the trained joint quality prediction model.

The artificial intelligence-based joint quality prediction method according to an embodiment of the present disclosure may be useful in predicting a fastening quality more accurately and in more detail than the existing equipment monitoring systems, and may strengthen the assembly quality.

### BRIEF DESCRIPTION OF THE DRAWINGS

FIG. 1 illustrates a flowchart of an artificial intelligence-based joint quality prediction method according to an embodiment of the present disclosure.

FIG. 2 illustrates a flowchart of an artificial intelligence-based joint quality prediction method according to an embodiment of the present disclosure.

FIG. 3 is a diagram for explaining a step of extracting and preprocessing raw data according to an embodiment of the present disclosure.

FIG. 4 illustrates a joint cross-section according to an embodiment of the present disclosure.

FIG. 5 shows an artificial intelligence-based joint quality prediction model according to an embodiment of the present disclosure.

FIG. 6 is a flowchart illustrating a method of training an artificial intelligence-based joint quality prediction model according to an embodiment of the present disclosure.

FIG. 7 is a diagram for explaining a K-fold cross validation step according to an embodiment of the present disclosure.

FIG. 8 is a diagram for explaining a step of determining a final class for joint quality prediction according to an embodiment of the present disclosure.

FIG. 9 is a diagram for explaining a step of determining a final class for joint quality prediction according to an embodiment of the present disclosure.

FIG. 10 is a diagram for explaining an artificial intelligence-based joint quality prediction method according to an embodiment of the present disclosure.

FIG. 11 is a diagram for explaining improvement of accuracy of a model according to additional training data according to an embodiment of the present disclosure.

FIG. 12 is a diagram for explaining software for real-time joint quality prediction by using a joint quality prediction model according to an embodiment of the present disclosure.

FIG. 13 is a diagram for explaining a computing device according to an embodiment of the present disclosure.

### DETAILED DESCRIPTION

With reference to the attached drawings, embodiments of the disclosure are described in detail below to enable one of ordinary skill in the art to implement the disclosure. However, the present disclosure may be implemented in many different forms and is not limited to the embodiments described herein. In order to clearly explain the disclosure in the drawings, parts irrelevant to the description are omitted, and like reference numerals designate like elements throughout the specification.

Throughout the specification and the claims, unless explicitly described to the contrary, the words such as “include,” “comprise,” etc., and variations such as “includes”, “comprises”, “including”, “comprising”, etc. should be understood to imply the inclusion of stated elements but not the exclusion of any other elements. The terms including ordinal numbers, such as first, second, etc. may be used to describe various elements, but the elements are not limited by the terms. The terms are used only for the purpose of distinguishing one element from another element.

The terms such as “-portion”, “-group”, “module”, and “means” described in the specification may mean a unit that processes at least one function or operation described in the specification, which may be implemented as hardware or software or a combination of hardware and software.

When a component, controller, device, element, apparatus, or the like of the present disclosure is described as having a purpose or performing an operation, function, or the like, the component, controller, device, element, apparatus, or the like should be considered herein as being “configured to” meet that purpose or to perform that operation or function. Each component, controller, device, element, apparatus, and the like may separately embody or be included with a processor and a memory, such as a non-transitory computer readable media, as part of the apparatus.

Hereinafter, embodiments of the present disclosure are described in detail with reference to the accompanying drawings.

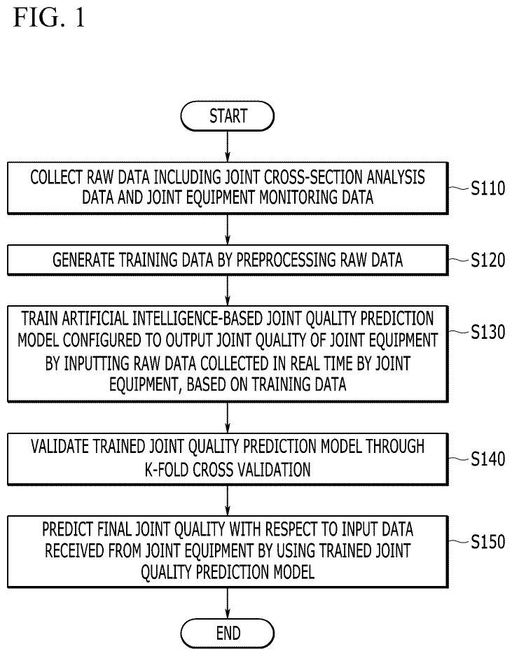

FIG. 1 illustrates a flowchart of an artificial intelligence-based joint quality prediction method according to an embodiment of the present disclosure.

Referring to FIG. 1, the artificial intelligence-based joint quality prediction method may include a step S110 of collecting raw data including joint cross-section analysis data and joint equipment monitoring data.

The step S110 of collecting the raw data including the joint cross-section analysis data and the joint equipment monitoring data may include a step of selecting a plurality of combinations with respect to heterogeneous materials and collecting the raw data from a test performed using a plurality of joint methods for each of the plurality of combinations.

The step S110 of collecting the raw data including the joint cross-section analysis data and the joint equipment monitoring data may include a step of collecting image data including a pressing force graph and a torque graph from the joint equipment as the raw data.

The artificial intelligence-based joint quality prediction method may include a step S120 of generating training data by preprocessing the raw data.

The step S120 of generating the training data by preprocessing the raw data may include a step of performing a preprocessing operation including data timing of the raw data, data section segmentation, noise removal, sampling transformation, and feature extraction.

The artificial intelligence-based joint quality prediction method may include a step S130 of training an artificial intelligence-based joint quality prediction model that outputs the joint quality of the joint equipment based on raw real-time data collected in real time (sometimes referred to herein as “real-time data”) from the joint equipment based on the training data. The real-time data may include joint equipment monitoring data collected by the joint equipment in real time, e.g., during production of a joint. The real-time data may be used to predict a joint quality of the joint using the trained joint quality prediction model trained based on the raw data.

The step S130 of training the artificial intelligence-based joint quality prediction model may include a step of training a convolutional neural network (CNN)-based joint quality prediction model.

The CNN-based joint quality prediction model may include three convolutional layers, two max pooling layers, and one fully connected layer.

The step of training the CNN-based joint quality prediction model may include a step of performing a convolutional operation to extract features of an image from the convolutional layers and generating a feature map from the image by using a plurality of filters.

The step of training the CNN-based joint quality prediction model may include a step of compressing the size of the feature map in the max pooling layers.

The step of training the CNN-based joint quality prediction model may include a step of calculating weights with respect to all features in the fully connected layer, classifying or predicting images.

The artificial intelligence-based joint quality prediction method may include a step S140 of validating the trained joint quality prediction model through a K-fold cross validation.

The step S140 of validating the trained joint quality prediction model through the K-fold cross validation may include a step of performing training K times by using part of the training data as validation data and generating K models.

The step S140 of validating the trained joint quality prediction model through the K-fold cross validation may include a step of calculating a prediction accuracy with respect to each of the K models by using evaluation data.

The step S140 of validating the trained joint quality prediction model through the K-fold cross validation may include a step of finally validating the performance of the joint quality prediction model through the average of prediction accuracies.

The artificial intelligence-based joint quality prediction method may include a step S150 of predicting a joint quality (e.g., sometimes referred herein as “final joint quality”) with respect to real-time data received from the joint equipment by using the trained joint quality prediction model.

The step S150 of predicting the final joint quality with respect to the joint equipment by using the trained joint quality prediction model may include a step of detecting whether the interlock length with respect to a self-piercing rivet (SPR) among joint methods is defective.

The step S150 of predicting the final joint quality with respect to the joint equipment by using the trained joint quality prediction model may include a step of detecting whether a step difference of a head portion and an internal gap of a flow drill screw (FDS) are defective.

The step S150 of predicting the final joint quality with respect to the joint equipment by using the trained joint quality prediction model may include a step of dividing the final joint quality into a plurality of classes and calculating probability values with respect to the plurality of classes.

The step S150 of predicting the final joint quality with respect to the joint equipment by using the trained joint quality prediction model may include a step of determining the final joint quality with respect to a specific class having a probability value greater than or equal to a preset standard (e.g., threshold or range).

The plurality of classes may include two or more of a normal class, a defective proximity class, or a defective class. In an embodiment, the plurality of classes may include at least a normal class, a defective proximity class, and a defective class.

The joint quality prediction model may be a classification model that classifies the real-time data into one of the two or more of the normal class, the defective proximity class, and the defective class. In an embodiment, the joint quality prediction model may be a classification model that classifies the real-time data into any one of the normal class, the defective proximity class, and the defective class

The artificial intelligence-based joint quality prediction method may include a step of selecting one of a plurality of joint schemes. The joint schemes may include the SPR and the FDS.

The artificial intelligence-based joint quality prediction method may include a step of receiving real-time data with respect to the selected joint scheme as the input data from the joint equipment.

The artificial intelligence-based joint quality prediction method may include a step of predicting the final joint quality with respect to the input data by using the joint quality prediction model trained based on the training data obtained by preprocessing the joint cross-section analysis data and the joint equipment monitoring data with respect to the selected joint scheme.

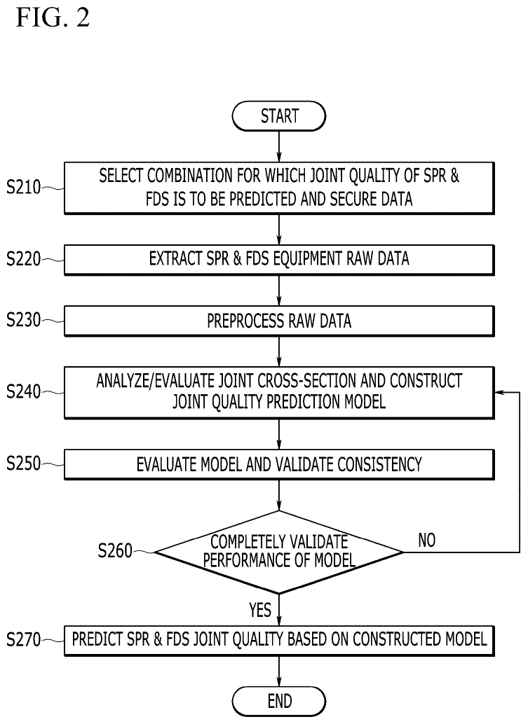

FIG. 2 illustrates a flowchart of an artificial intelligence-based joint quality prediction method according to an embodiment of the present disclosure.

Referring to FIG. 2, the artificial intelligence-based joint quality prediction method may include a step S210 that may include selecting a combination for which the joint quality of an SPR and/or an FDS is to be predicted.

The step S210 may also include securing data through an SPR/FDS specimen test or an actual vehicle destruction test by an appropriate number of times.

The artificial intelligence-based joint quality prediction method may include a step S220 of extracting raw data including equipment monitoring data from a control panel of SPR/FDS equipment when the test is completed.

The artificial intelligence-based joint quality prediction method may include a step 230 of performing a preprocessing operation including a data timing task, a data noise removal tasks, etc., that may be needed for CNN-based modeling construction.

The artificial intelligence-based joint quality prediction method may include a step S240 that may include analyzing and evaluating the cross-section of a specimen or actual vehicle so as to secure test result data including joint cross-section analysis data after obtaining the raw data from joint equipment.

The step S240 may also include constructing an artificial intelligence-based joint quality prediction model based on the equipment monitoring data and the joint cross-section analysis data.

The joint quality prediction model may output the joint quality of the SPR/FDS joint equipment based on real-time data collected in real time by the joint equipment.

The artificial intelligence-based joint quality prediction method may include a step S250 of validating whether the joint quality prediction model has consistency by dividing training data into training/validation/evaluation data so as to evaluate the constructed model.

The artificial intelligence-based joint quality prediction method may include a step of validating the trained joint quality prediction model through a K-fold cross validation.

In an embodiment, the artificial intelligence-based joint quality prediction method may further secure data and evaluate the model through a new test.

The artificial intelligence-based joint quality prediction method may include a step S260 of determining whether the consistency of the joint quality prediction model has been secured by a desired level.

The artificial intelligence-based joint quality prediction method may include a step S270 of predicting the SPR & FDS joint quality based on the constructed model when the validation of the model performance is completed.

In various embodiments, the artificial intelligence-based joint quality prediction method may provide prediction to a user based on the constructed model, thereby allowing the user to predict the joint quality of joint equipment based on raw data of the equipment.

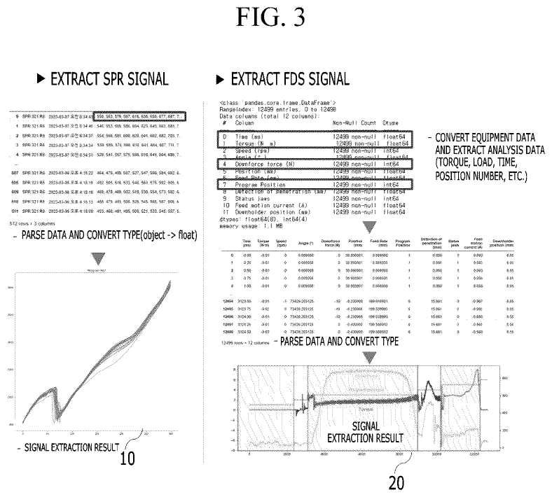

FIG. 3 is a diagram for explaining a step of extracting and preprocessing raw data according to an embodiment of the present disclosure. FIG. 3 shows an example of the step of extracting and preprocessing raw data of each of an SPR and an FDS.

Referring to FIG. 3, an artificial intelligence-based joint quality prediction method according to an embodiment may include a step of converting, extracting, and processing data from equipment data into analyzable data.

In an embodiment, the artificial intelligence-based joint quality prediction method may include a step of extracting an SPR signal from equipment and preprocessing the SPR signal.

For example, the artificial intelligence-based joint quality prediction method may include a step of extracting a device name, date/time, a sensor value, etc. included in the equipment data.

The artificial intelligence-based joint quality prediction method may include a step of parsing the extracted data and transforming a type. SPR signal extraction and preprocessing results 10 may be represented as a graph image.

In an embodiment, the artificial intelligence-based joint quality prediction method may include a step of extracting an FDS signal.

For example, the artificial intelligence-based joint quality prediction method may include a step of converting the equipment data and extracting analysis data. The analysis data may include torque, load, time, position number, etc.

The artificial intelligence-based joint quality prediction method may include a step of parsing the analysis data and converting a type.

FDS signal extraction and preprocessing results 20 may be represented as a graph image.

The artificial intelligence-based joint quality prediction method may include a step of preprocessing raw data to improve the performance of a joint quality prediction model. Preprocessing may include data timing, data section segmentation, noise removal, and feature extraction.

For example, data section segmentation may subdivide the raw data extracted from the equipment into a penetration section, a thread section, and a tightening section according to a joint progress stage.

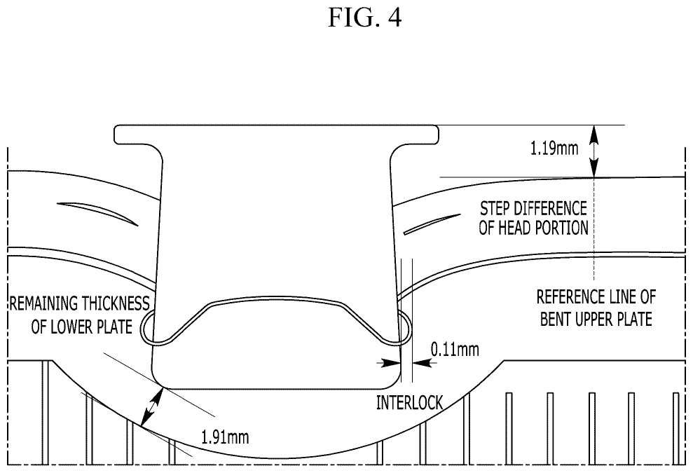

FIG. 4 illustrates a joint cross-section according to an embodiment of the present disclosure. FIG. 4 shows an SPR fastening state.

Referring to FIG. 4, three factors for determining joint quality when an SPR is fastened may include a step difference of a head portion, a remaining thickness of a lower plate, and an interlock.

For example, the criteria for determining normal quality in an SPR joint may include the step difference of the head portion as 0.2 mm to 0.3 mm, the remaining thickness of the lower plate as 0.1 mm or more or 0.2 mm or more, and the interlock as 0.15 mm or more.

The artificial intelligence-based joint quality prediction method may include a step of photographing a joint cross section through image processing, setting an image scale, and measuring a length or a thickness for each element.

The artificial intelligence-based joint quality prediction method may divide quality into a plurality of classes. For example, the classes dividing the quality may include a normal class (class1), a defective proximity class (class2), and a defective class (class 3) for each element.

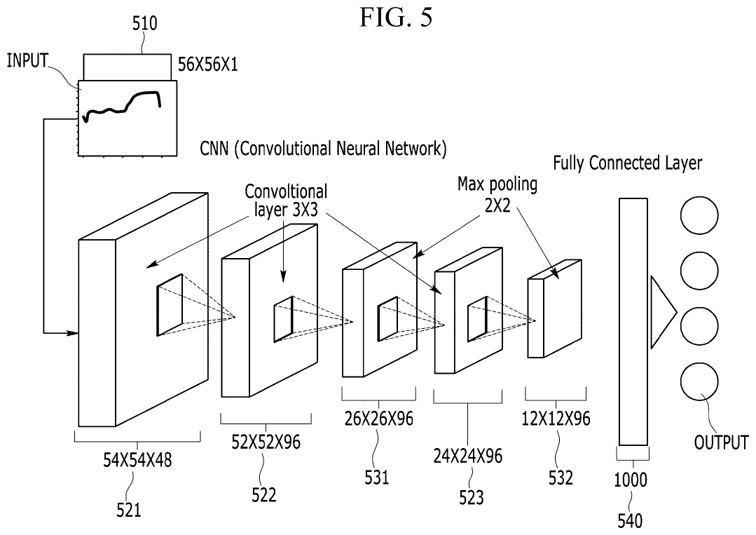

FIG. 5 shows an artificial intelligence-based joint quality prediction model according to an embodiment of the present disclosure.

Referring to FIG. 5, a CNN-based joint quality prediction model according to an embodiment may include one or more convolutional layers, one or more pooling layers (e.g., one or more max pooling layers), and one or more connected layers (e.g., one or more fully connected layers). For example, as illustrated in FIG. 5, a CNN-based joint quality prediction model may include three convolutional layers 521, 522, and 523, two pooling layers 531 and 532, and a connected layer 540. The pooling layers 531 and 532 may be max pooling layers. The connected layer 540 may be a fully connected layer.

The CNN-based joint quality prediction model may include an input layer 510 that receives preprocessed training data as an input INPUT.

The CNN-based joint quality prediction model may receive image data 56×56×1 in the form of a multidimensional arrangement as training data in the input layer 510.

The training data may be image data generated through matrix-based image conversion in which a logic one (1) is input to positions corresponding to x-coordinate and y-coordinate of each of pressing force data and torque data of the joint equipment and a logic zero (0) is input to the remaining positions.

The CNN-based joint quality prediction model may perform a convolutional operation to extract features of the image data from the convolutional layer, and may generate a feature map 54×54×48 from the image data by using a plurality of filters.

A step of training the CNN-based joint quality prediction model may include compressing the size of the feature map in a max pooling layer.

The step of training the CNN-based joint quality prediction model may include determining (e.g., calculating) weights with respect to the features in a fully connected layer, and classify or predict images.

For example, the CNN-based joint quality prediction model may derive a probability for each class from a final output OUTPUT by stacking multiple layers. A class with the highest probability may be determined as a final joint quality.

The CNN-based joint quality prediction model may be a classification model that classifies input data into one of a normal class, a defective proximity class, or a defective class.

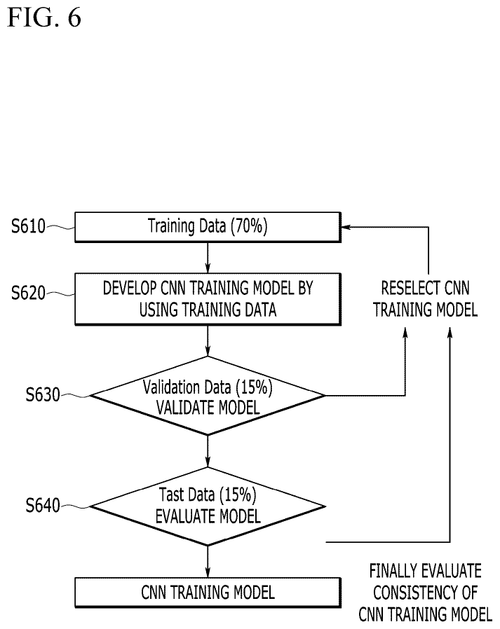

FIG. 6 is a flowchart illustrating a step of training an artificial intelligence-based joint quality prediction model according to an embodiment of the present disclosure.

Referring to FIG. 6, the step of training the CNN-based joint quality prediction model may include a step S610 of classifying training data extracted from raw data of joint equipment into training data of 70%, validation data of 15%, and evaluation data of 15%.

The step of training the artificial intelligence-based joint quality prediction model may include a step S620 of training a CNN-based training model by using the training data.

The step of training the artificial intelligence-based joint quality prediction model may include a step S630 of validating the trained model by using the validation data.

The step 630 of validating the trained model by using the validation data may include a step of proceeding to a model evaluation step when validation is successful, and re-selecting the training model when validation fails.

The step of training the artificial intelligence-based joint quality prediction model may include a step S640 of evaluating the model by using the evaluation data.

In the step of evaluating the model by using the evaluation data, the model that has passed suitability evaluation may be determined as the joint quality prediction model.

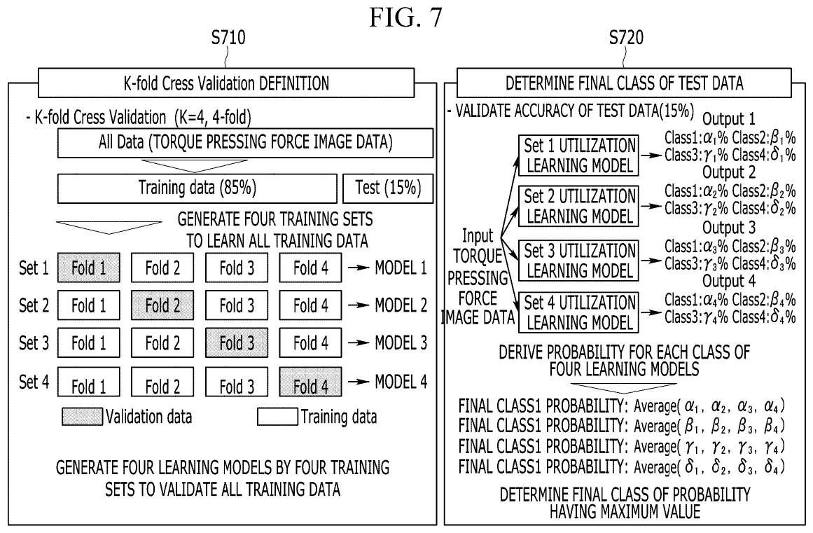

FIG. 7 is a diagram for explaining a K-fold cross validation step according to an embodiment of the present disclosure.

FIG. 7 is a diagram for explaining step S710 of generating a plurality of models for a K-fold cross validation and step S720 of determining a final class in the K-fold cross verification step. For example, K may be determined to be 4.

An artificial intelligence-based joint quality prediction method may include a step of predicting a final joint quality of input data.

Referring to FIG. 7, the step of predicting the final joint quality of the input data may include a step of performing predictions K times by using the joint quality prediction model through the K-fold cross validation.

The step of predicting the final joint quality of the input data may include a step of determining the final joint quality based on a calculated average of K prediction results.

The step S710 of generating the plurality of models for the K-fold cross validation may include a step of classifying torque and pressing force image data received as input data into training data of 85% and evaluation data of 15%.

The step S710 of generating the plurality of models for the K-fold cross validation may include a step of generating four (K=4) models each trained with training data. The four models each may be trained with a training set. The training set may include validation data and training data.

The step S720 of determining the final class may include a step of classifying the final joint quality into a plurality of classes and calculating prediction results as probability values with respect to the plurality of classes, respectively.

The probability value of each model for each class may correspond to the prediction result of each model.

Accordingly, step S720 of determining the final class may include a step of deriving a probability for each class from the input data by using each of the four models.

The classes may include a first class class1, a second class class2, a third class class3, and a fourth class class4.

For example, the first class class1 may be a normal class, the second class class2 may be a defective proximity class, the third class class3 may be a defective class, and the fourth class class4 may be a pre-hole defective class.

The step of deriving the probability for each class from the input data by using each of the four models includes a step of deriving the probability for each class by using each of the models.

The step S720 of determining the final class may include a step of calculating an average of probabilities derived from a plurality of models for each class.

For example, the step S720 of determining the final class may include a step of calculating a probability average for each class based on a probability output1 for each class calculated through model 1 (set1 utilization learning model), a probability output2 for each class calculated through model 2 (set2 utilization learning model), a probability output3 for each class calculated through model 3 (set3 utilization learning model), and a probability output4 for each class calculated through model 4 (set4 utilization learning model).

The step S720 of determining the final class may include a step of determining a class having the largest probability average among the probability average derived for each class as the final class.

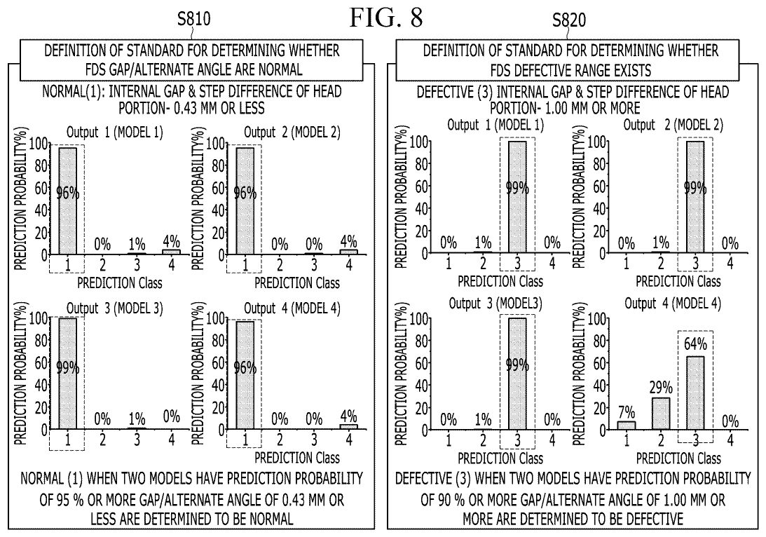

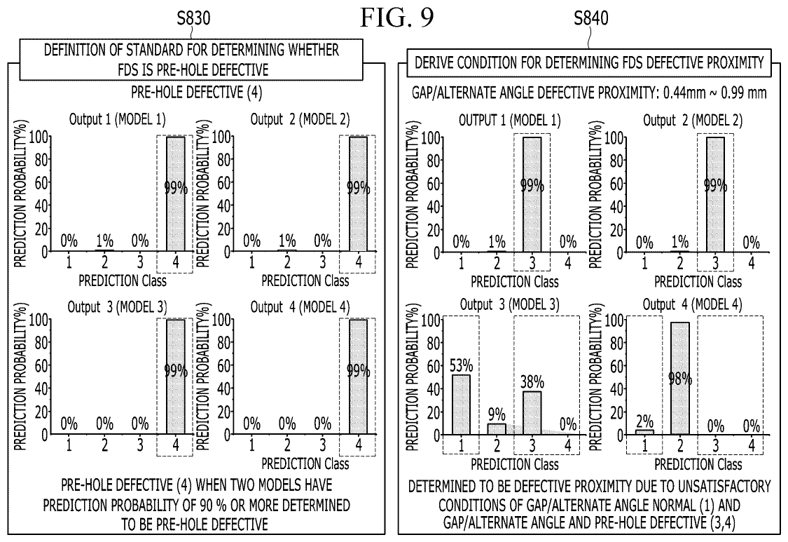

FIG. 8 is a diagram for explaining a step of determining a final class for joint quality prediction according to an embodiment of the present disclosure. FIG. 9 is a diagram for explaining a step of determining a final class for joint quality prediction according to an embodiment of the present disclosure.

FIGS. 8 and 9 illustrate an FDS as an example. The FDS is described with reference to FIG. 7.

The step of determining the final class for joint quality prediction may include step S810 of finally determining a normal class, step S820 of finally determining a defective class, step S830 of finally determining a pre-hole defective class, and step S840 of finally determining a defective proximity class.

The step of determining the final class for joint quality prediction may include a step of determining the final joint quality with respect to a specific class when a certain percentage (e.g., more than half) of prediction results include the specific class having a probability value satisfying a preset standard. The preset standard may be that the certain percentage (e.g., more than half) of prediction results include the specific class having a probability greater than or equal to a preset threshold or is within a preset range.

Referring to FIG. 8, step S810 of finally determining the normal class may include a step of determining a first class as the final class when two or more of the four models have a prediction result in which a probability value of the first class (normal) is 95% or more.

In FIG. 8, a model 1, a model 2, a model 3, and a model 4 all determine the first class as the probability of 95% or more. Therefore, the quality of an internal gap and a step difference of a head portion of the FDS may finally be determined to be normal.

In an example, the internal gap and the step difference of the head portion of the FDS that is equal to or less that the preset threshold (e.g., 0.43 mm) may be predicted to be normal.

For example, step S820 of finally determining the defective class may include a step of determining a third class as the final class when two or more of the four models have a prediction result in which a probability value of the third class (defective) is 90% or more.

In FIG. 8, the model 1, the model 2, and the model 3 all determine the third class as the probability of 95% or more. Therefore, the quality of the internal gap and the step difference of the head portion of the FDS may be finally determined to be defective.

In an example, the internal gap and the step difference of the head portion of the FDS that is equal to or greater than the preset threshold (e.g., 1.00 mm) may be predicted to be defective.

In an example, step S830 of finally determining the pre-hole defective class may include determining a fourth class as the final class when two or more of the four models have a prediction result in which a probability value of the fourth class (pre-hole defective) is 90% or more.

Referring to FIG. 9, the model 1, the model 2, the model 3, and the model 4 all determine the fourth class as the probability of 90% or more, in the illustrated embodiment. Therefore, the quality of the internal gap and the step difference of the head portion of the FDS may be finally determined to be pre-hole defective.

Accordingly, the internal gap and the step difference of the head portion of the FDS may be predicted to be pre-hole defective.

For example, step S840 of finally determining the defective proximity class may include a step of determining a second class as the final class when two or more of the four models have a prediction result in which a probability value of the second class (defect proximity) is 90% or more.

In FIG. 9, both the model 1 and the model 4 determine the second class as the probability of 90% or more. Therefore, the quality of the internal gap and the step difference of the head portion of the FDS may be finally determined to be defective proximity.

In addition, when the prediction results of the models 1 to 4 are not finally satisfied with any of class 1, class 3, and class 4, step S840 of finally determining the defective proximity class may include a step of determining the second class as the final class.

In an example, internal gap and the step difference of the head portion of the FDS that is within the preset range (e.g., 0.44 mm to 0.99 mm).

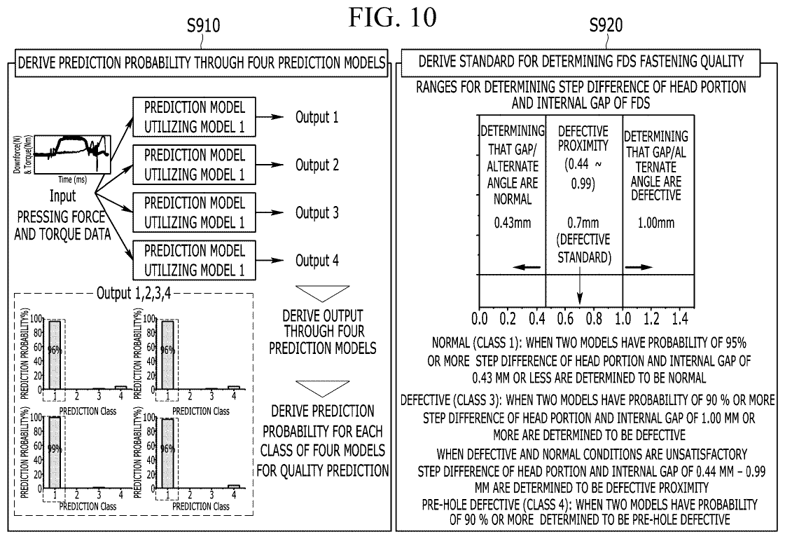

FIG. 10 is a diagram for explaining an artificial intelligence-based joint quality prediction method according to an embodiment of the present disclosure. The artificial intelligence-based joint quality prediction method of FIG. 10 is described with reference to FIGS. 8 and 9.

In FIG. 10, input data (input) may be provided as image data generated through matrix-based image conversion in which a logic one (1) is input to positions corresponding to x-coordinate and y-coordinate of each of pressing force data and torque data and a logic zero (0) is input to the remaining positions.

The artificial intelligence-based joint quality prediction method may include a step S910 of calculating a plurality of prediction results (outputs) by using a plurality of joint quality prediction models by inputting the pressing force and the torque data.

For example, the artificial intelligence-based joint quality prediction method may calculate four prediction results by using four joint quality prediction models and calculate a prediction probability for each class based on the four prediction results.

The artificial intelligence-based joint quality prediction method may include a step S920 of determining a final class for joint quality prediction.

The artificial intelligence-based joint quality prediction method may include a step of determining, as the final class, any one of classes including normal, defective proximity, defective, and pre-hole defective determinable ranges calculated in advance based on joint cross-section analysis data.

For example, the artificial intelligence-based joint quality prediction method may determine an FDS joint quality as a normal determinable range when prediction results of two or more models represent the class 1.

For example, the normal range of a step difference of a head portion and an internal gap of an FDS may be 0.43 mm or less, the defect range thereof may be 1.00 mm or more, and the defect proximity range thereof may be 0.44 mm to 0.99 mm.

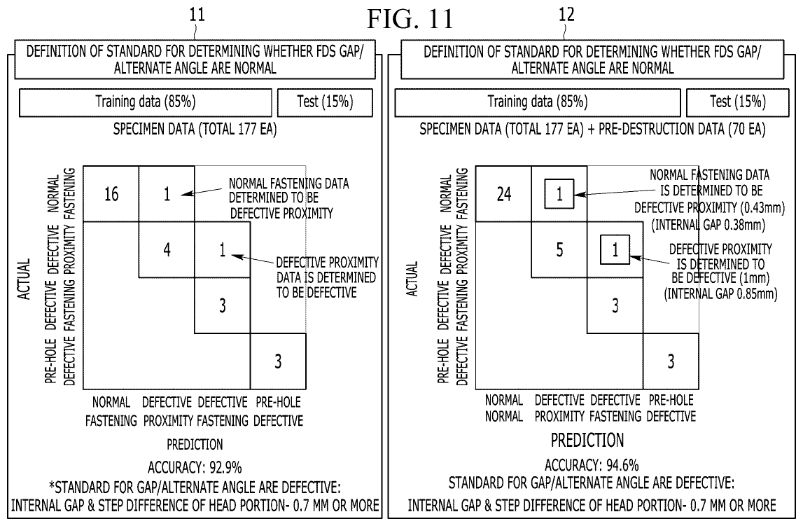

FIG. 11 is a diagram for explaining improvement of accuracy of a model according to additional training data according to an embodiment of the present disclosure.

FIG. 11 is a diagram illustrating the improved accuracy of a prediction result when actual vehicle data is additionally applied to the existing input data.

FIG. 11 illustrates a result 11 of accuracy analysis of a learning model through the existing specimen data and a result 12 of accuracy analysis of the learning model when actual vehicle pre-destruction data is learned together in addition to the existing specimen data.

Referring to FIG. 11, when comparing the two results 11 and 12, the result 12 of accuracy analysis of the learning model through the specimen data and the actual vehicle pre-destruction data shows an accuracy of 94.6%, and the result 11 of accuracy analysis of the learning model through the existing specimen data shows an accuracy of 92.9%.

For example, the result 11 of accuracy analysis of the learning model through the existing specimen data has 26 correct determination results and 2 incorrect determination results.

The result 12 of accuracy analysis of the learning model through the specimen data and the actual vehicle pre-destruction data have 35 correct determination results and 2 incorrect determination results.

Therefore, it may be seen that the result 12 of accuracy analysis of the learning model through the specimen data and the actual vehicle pre-destruction data has a high accuracy by 1.7%.

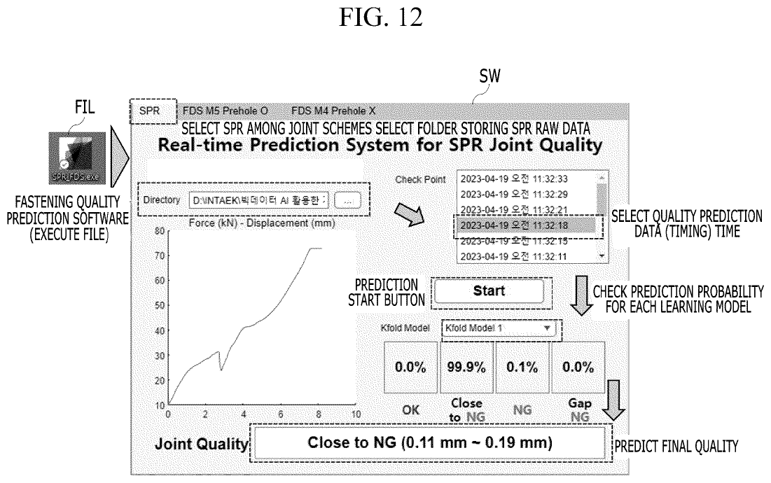

FIG. 12 is a diagram for explaining software for real-time joint quality prediction by using a joint quality prediction model according to an embodiment of the present disclosure.

Referring to FIG. 12, an artificial intelligence-based joint quality prediction method through software SW may be driven when a user clicks on an executable file FIL of the software SW.

The artificial intelligence-based joint quality prediction method may include a step of inputting at least one selected from an SPR or an FDS. When the user selects either the SPR or the FDS, a selected scheme may be input. FIG. 12 illustrates a case where the SPR is selected as an example.

The artificial intelligence-based joint quality prediction method may include a step of detecting whether an interlock length of a joint cross-section in the SPR is normal, defective proximity, or defective when a folder storing input data is selected.

The artificial intelligence-based joint quality prediction method may include a step of detecting whether a step difference of a head portion and an internal gap of the joint cross-section in the FDS is normal, defective proximity, defective, or pre-hole defective when the folder storing the input data is selected.

In FIG. 12, when a quality prediction data time is selected and a prediction start button is input, the artificial intelligence-based joint quality prediction method may predict quality through a joint quality prediction model trained with respect to the corresponding time.

The user may check a result for each prediction model through an output unit of the software SW.

In addition, the user may check a final quality prediction result calculated based on the prediction result for each prediction model through the software SW.

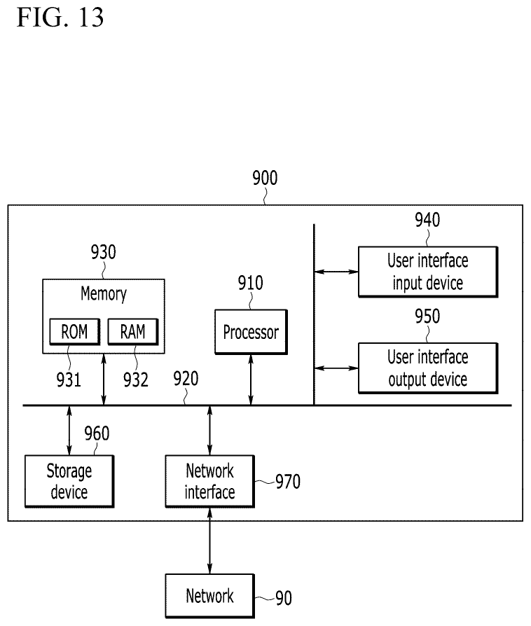

FIG. 13 is a diagram illustrating a computing device according to an embodiment of the present disclosure.

Referring to FIG. 13, an artificial intelligence-based joint quality prediction method according to embodiments may be implemented by using a computing device 900.

The computing device 900 may include at least one of a processor 910, a memory 930, a user interface input device 940, a user interface output device 950, and a storage device 960 that communicate with each other over a bus 920. The computing device 900 may also include a network interface 970 that is electrically connected to a network 90. The network interface 970 may transmit or receive signals to and from other entities through the network 90.

The processor 910 may be implemented as a variety of types, such as a Micro Controller Unit (MCU), Application Processor (AP), Central Processing Unit (CPU), Graphic Processing Unit (GPU), and Neural Processing Unit (NPU), and may be any semiconductor device that executes commands stored in the memory 930 or the storage device 960. The processor 910 may be configured to implement the functions and methods described above with respect to FIGS. 1-12.

The memory 930 and the storage device 960 may include various types of volatile or non-volatile storage media. For example, the memory 930 may include read-only memory (ROM) 931 and random access memory (RAM) 932. In the embodiment, the memory 930 may be located inside or outside the processor 910, and the memory 930 may be connected to the processor 910 through various known means.

In some embodiments, at least some components or functions of the artificial intelligence-based joint quality prediction method according to the embodiments may be implemented in a program or software executed by the computing device 900, and the program or software may be stored in a computer-readable medium.

In some embodiments, at least some components or functions of the artificial intelligence-based joint quality prediction method according to the embodiments may be implemented by using hardware or circuit of the computing device 900, or may be implemented as separate hardware or circuit that may be electrically connected to the computing device 900.

Although the embodiments of the present disclosure have been described in detail above, the scope of the present disclosure is not limited thereto. Rather, various modifications and improvements made by those of ordinary skill in the art to which the present disclosure pertains are also included in the scope of the present disclosure.

What is claimed is:

1. An artificial intelligence-based joint quality prediction method comprising:
collecting raw data including joint cross-section analysis data and joint equipment monitoring data;
generating training data by preprocessing the raw data;
training, based on the training data, a joint quality prediction model configured to output joint quality of joint equipment based on real-time data collected in real time by the joint equipment; and
validating the trained joint quality prediction model through a K-fold cross validation.

2. The artificial intelligence-based joint quality prediction method of claim 1, further comprising predicting the joint quality with respect to the joint equipment by using the trained joint quality prediction model, including performing one or both of:
determining whether an interlock length of a self-piercing rivet (SPR) is defective; or
determining whether a step difference of a head portion and an internal gap of a flow drill screw (FDS) are defective.

3. The artificial intelligence-based joint quality prediction method of

1. wherein collecting the raw data including joint cross-section analysis data and joint equipment monitoring data includes:
selecting a plurality of combinations with respect to heterogeneous materials; and
collecting the raw data from a test performed using a plurality of joint methods with respect to each of the plurality of combinations.

4. The artificial intelligence-based joint quality prediction method of claim 1, wherein collecting the raw data including joint cross-section analysis data and joint equipment monitoring data includes collecting image data including a pressing force graph and a torque graph from the joint equipment as the raw data.

5. The artificial intelligence-based joint quality prediction method of claim 1, wherein generating the training data includes performing a preprocessing operation including one or more of data timing of the raw data, data section segmentation, noise removal, sampling transformation, or feature extraction.

6. The artificial intelligence-based joint quality prediction method of claim 1, wherein training the joint quality prediction model includes training a convolutional neural network (CNN)-based joint quality prediction model, wherein the CNN-based joint quality prediction model includes one or more convolutional layers, one or more pooling layers, and one or more connected layers.

7. The artificial intelligence-based joint quality prediction method of claim 6, wherein training the CNN-based joint quality prediction model includes:
performing a convolutional operation to extract features of image data from the one or more convolutional layers and generating a feature map from the image data by using a plurality of filters;
compressing a size of the feature map in the one or more pooling layers; and
determining weights with respect to the features in the one or more connected layers.

8. The artificial intelligence-based joint quality prediction method of claim 1, wherein validating the trained joint quality prediction model through the K-fold cross validation includes:
performing training K times by using part of the training data as validation data and generating K models;
determining prediction accuracies with respect to the K models by using part of the training data as evaluation data; and
validating the performance of the joint quality prediction model based on an average of the prediction accuracies.

9. The artificial intelligence-based joint quality prediction method of claim 2, wherein predicting the joint quality with respect to the joint equipment by using the trained joint quality prediction model further includes:
determining probability values of the joint quality with respect to a plurality of classes; and
determining the joint quality as a specific class, among the plurality of classes, having a probability value satisfying a preset standard.

10. The artificial intelligence-based joint quality prediction method of claim 9, wherein:
the plurality of classes includes at least a normal class, a defective proximity class, and a defective class; and
the joint quality prediction model is a classification model configured to classify the real-time data into one of the normal class, the defective proximity class, or the defective class.

11. An artificial intelligence-based joint quality prediction method comprising:
selecting a joint scheme of a plurality of joint schemes;
receiving real-time data with respect to the selected joint scheme as input data from joint equipment; and
predicting a joint quality based on the input data by using a joint quality prediction model trained based on training data obtained by preprocessing joint cross-section analysis data and joint equipment monitoring data with respect to the selected joint scheme.

12. The artificial intelligence-based joint quality prediction method of claim 11, wherein selecting the joint scheme of the plurality of joint schemes includes selecting at least one of a self-piercing rivet (SPR) or a flow drill screw (FDS) as the joint scheme.

13. The artificial intelligence-based joint quality prediction method of claim 12, wherein receiving the real-time data with respect to the selected joint scheme as the input data from the joint equipment includes inputting pressing force data and torque data of the joint equipment provided in a graph as the input data.

14. The artificial intelligence-based joint quality prediction method of claim 13, wherein inputting the pressing force data and the torque data of the joint equipment provided in the graph as the input data includes
inputting, as the input data, image data generated through matrix-based image conversion in which a logic one (1) is input to positions corresponding to an x-coordinate and a y-coordinate of each of the pressing force data and the torque data and a logic zero (0) is input to remaining positions.

15. The artificial intelligence-based joint quality prediction method of claim 14, wherein predicting the joint quality based on the input data includes:
based on selecting the SPR as the selection of the joint scheme, predicting a joint cross-section quality with respect to at least one of a step difference of a head portion, a remaining thickness of a lower plate, or an interlock length, and
based on selecting the FDS as the selection of the joint scheme, predicting the joint cross-section quality with respect to at least one of a step difference of a head portion, an internal gap between plates, or a diagonal fastening.

16. The artificial intelligence-based joint quality prediction method of claim 15, wherein predicting the joint quality based on the input data further includes:
performing predictions K times by using the joint quality prediction model through a K-fold cross validation; and
determining the joint quality based on a calculated average of K prediction results.

17. The artificial intelligence-based joint quality prediction method of claim 16, wherein predicting the joint quality based on the input data further includes:
determining prediction results as probability values with respect to a plurality of classes; and
determining the joint quality with respect to a specific class based on determining that a certain percentage of the prediction results include the specific class having a probability value satisfying a preset standard.

18. The artificial intelligence-based joint quality prediction method of claim 17, wherein:
the plurality of classes includes at least a normal class, a defective proximity class, and a defective class; and
the joint quality prediction model is a classification model configured to classify the input data into one of the normal class, the defective proximity class, or the defective class.

19. The artificial intelligence-based joint quality prediction method of claim 11, wherein predicting the joint quality based on the input data by using the joint quality prediction model includes determining whether an interlock length of a joint cross-section in an SPR is normal, defective proximity, or defective by using a pressing force graph and a torque graph of the joint equipment as the input data.

20. The artificial intelligence-based joint quality prediction method of claim 11, wherein predicting the joint quality of the input data by using the joint quality prediction model includes determining whether a step difference of a head portion and an internal gap of a joint cross-section in an FDS is normal, defective proximity, defective, or pre-hole defective by using a pressing force graph and a torque graph of the joint equipment as the input data.
